(19) United States
(12) Patent Application Publication
(10) Pub. No.: US 2006/0094268 A1
(43) Pub. Date: May 4, 2006

(54) Conductive terminal and the electrical connector using the conductive terminal

(76) Inventor: Yin Hao, Shanghai (CN)

Correspondence Address: Robert J Zeitler;Molex Incorporated, 2222 Wellington Court, Lisle, IL, 60532, US

(21) Appl. No.: 10/537,929

(22) PCT Filed: Jan. 29, 2004
(86) PCT No.: PCT/US04/02622

§ 371 Date: Jun. 7, 2005

(30) Foreign Application Priority Data
Jan. 29, 2003 (CN) 03202283.2

(51) Int. Cl. H05K 1/00

(52) U.S. Cl. 439/83

(57) ABSTRACT

A conductive terminal and the electrical connector using the conductive terminal, the conductive terminal is received in a terminal channel defined in an insulative housing of the electrical connector which can transmit signal between an electronic component and a circuit board. The conductive terminal has a first wall, a second wall connecting with the first wall in a certain angle and a third wall connecting with the second wall in a certain angle and opposite to the first wall. The conductive terminal forms a contact portion electrically connecting with the electronic component and a mounting portion electrically connecting with the circuit board via the solder ball. The mounting portion defines a pyramidal space extending out of the insulative housing for receiving the solder ball. When the solder ball melts, the solder ball and the pyramidal space have easily orientation and steadily connecting effect.

### FIELD OF THE INVENTION

The present invention generally relates to a conductive terminal and, more particularly, to a conductive terminal used in an electrical connector which can transmit signals between an electronic component and a circuit board via a solder ball connected with the circuit board.

### BACKGROUND OF THE INVENTION

Referring to FIG. 1 to 3, as disclosed in T.W. patent application No. 087216147, publication No. 392975, an electrical connector 1 is a zero insertion force (“ZIF”) electrical connector for electrically interconnecting a central processing unit (“CPU”) and a mainboard used in computer device. The electrical connector 1 comprises an insulative housing 10 and a plurality of conductive terminals 2. Each of the conductive terminals 2 electrically connects with the circuit board 30 through surface mounting technology (“SMT”) by pre-setting a solder ball 23 onto an end thereof.

The insulative housing 10 of the electrical connector 1 has a mounting surface 12 on the bottom surface thereof which is positioned proximate to the circuit board 30 and a receiving surface 11 on the top surface thereof for supporting the electronic component. The insulative housing 10 also defines a plurality of through holes 13 extending between the mounting surface 12 and the receiving surface 11.

Each of the conductive terminals 2 respectively received in the corresponding through holes 13 forms a contact portion 20 extending toward the receiving surface 11 and an end portion 21 opposite extending to the mounting surface 12. The end portion 21 has a bottom surface 22 for soldering with the corresponding solder ball 23.

To improve successful rate of pre-setting the solder ball 23 onto the end portion 21 of the conductive terminals 2, the end portion 21 forms a disk-shape plane approximately 90 degrees bending to the contact portion 20 so that the end portion 21 and the mounting surface 12 of the insulative housing 10 are approximately located in the same plane. The plane disk-shape end portion 21 provides a larger area of pre-setting the solder ball 23 so as to steadily pre-set the solder ball 23. In addition, a plurality of protrusions 25 integrally extend from the side of the end portion 21 for preventing the solder ball 23 dropping from the bottom surface 22 of the end portion 21.

To applying the SMT of pre-setting the solder ball 23, one end of the conductive terminal 2 must have a structure of easily locating and connecting the solder ball 23. The above method is only one of the resolving schemes with which the end portion of the conductive terminal 2 has different structures to locate and connect the solder ball 23. The present invention provides an improved conductive terminal to locate and connect the solder ball 23.

### SUMMARY OF THE INVENTION

An object of the present invention is to provide a conductive terminal that easily locate and steadily connect with a solder ball.

Another object of the present invention is to provide an electrical connector using the conductive terminals.

The conductive terminals of the present invention are received in a plurality of terminal channels of an insulative housing of the electrical connector which can transmit signals between an electronic component and a circuit board. The conductive terminal has a first wall, a second wall connecting with the first wall in a certain angle and a third wall connecting with the second wall in a certain angle and opposite to the first wall. The conductive terminal forms a contact portion electrically connecting with the electronic component and a mounting portion electrically connecting with the circuit board via the solder ball. The mounting portion defines a pyramidal space extending out of the insulative housing for receiving the solder ball.

The electrical connector of the present invention for connecting between the electronic component and the circuit board via a plurality of solder balls soldering onto the circuit bard, comprises an insulative housing having a mounting surface which is positioned proximate to the circuit board and a receiving surface for supporting the electronic component The insulative housing defines a plurality of terminal channels extending through the mounting surface and the receiving surface. The electrical connector also comprises a plurality of conductive terminals respectively received in the corresponding terminal channels. The conductive terminal has a first wall, a second wall connecting with the first wall in a certain angle and a third wall connecting with the second wall in a certain angle and opposite to the first wall. The conductive terminal forms a contact portion electrically connecting with the electronic component and a mounting portion electrically connecting with the circuit board via the solder ball. The mounting portion defines a pyramidal space extending out of the mounting surface of the insulative housing for receiving the solder ball.

The mounting portion defines the pyramidal space by using a side wall connecting with an end of the first wall which circles around a fictitious central line as an axis.

The mounting portion can also comprises a first side arm connecting with an end of the first wall and a second side arm connecting with an end of the third wall. The first side arm and the second side arm separately extend out of the insulative housing and define the pyramidal space.

The pyramidal structure of the conductive terminal can easily receive and locate the solder ball. When the solder ball melts, tin and the conductive terminals can solid adhere and have larger adhere area so as to ensure adhere stability.

Other objects, features and advantages of the invention will be apparent from the following detailed description taken in connection with the accompanying drawings.

### BRIEF DESCRIPTION OF THE DRAWINGS

The features of this invention which are believed to be novel are set forth with particularity in the appended claims. The invention, together with its objects and the advantages thereof, may be best understood by reference to the following description taken in conjunction with the accompanying drawings, in which like reference numerals identify like elements in the figures and in which:

FIG. 1 is a partial sectional view illustrating a conventional electrical connector;

FIG. 2 is a side partial sectional view illustrating of FIG. 1;

FIG. 3 is a perspective view of a conductive terminal of the conventional electrical connector of FIG. 1;

FIG. 4 is a perspective view of a conductive terminal and an insulative housing of the first embodiment of the present invention;

FIG. 5 is another plan view of FIG. 4;

FIG. 6 is a side view of a solder ball located in a mounting portion of the conductive terminal of the first embodiment of the present invention;

FIG. 7 is a perspective view of a conductive terminal and an insulative housing of the second embodiment of the present invention;

FIG. 8 is another plan view of FIG. 7;

FIG. 9 is a side view of the solder ball located in a mounting portion of the conductive terminal of the second embodiment of the present invention;

FIG. 10 is a perspective view of the conductive terminal having a horizontal portion of the present invention; and

FIG. 11 is a side view of the solder ball located in a mounting portion of the conductive terminal of FIG. 10.

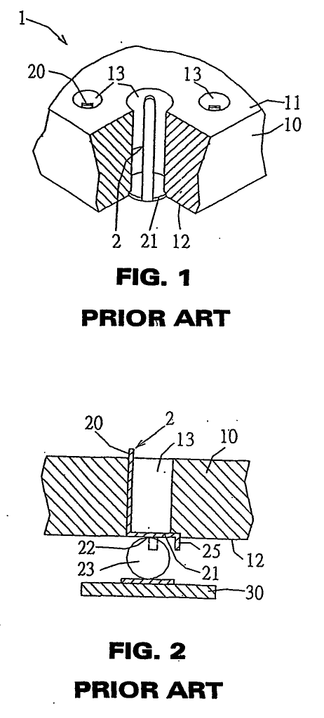

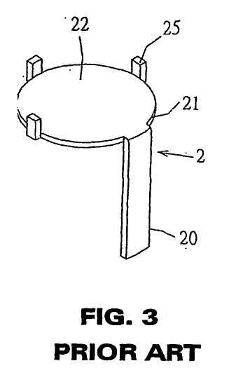

### DETAILED DESCRIPTION OF THE DISCLOSED EMBODIMENTS

While the invention may be susceptible to embodiment in different forms, there is shown in the drawings, and herein will be described in detail, a specific embodiment with the understanding that the present disclosure is to be considered an exemplification of the principles of the invention, and is not intended to limit the invention to that as illustrated and described herein.

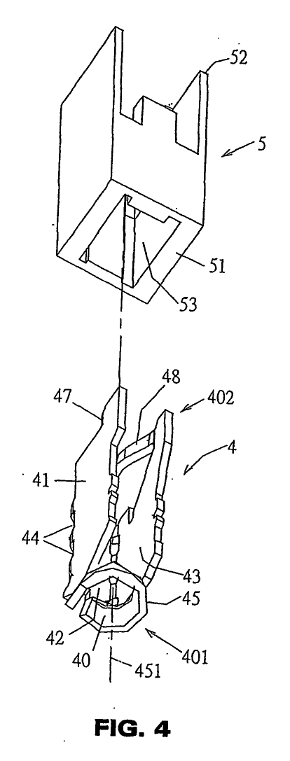

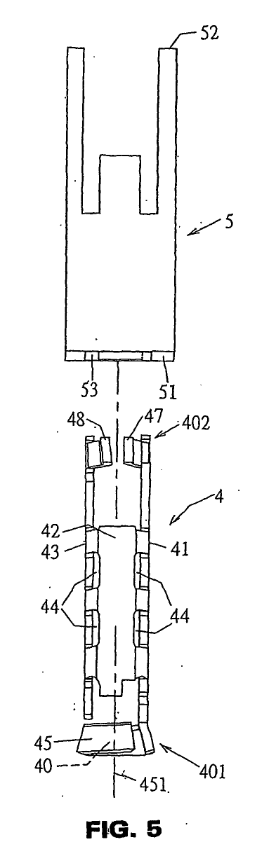

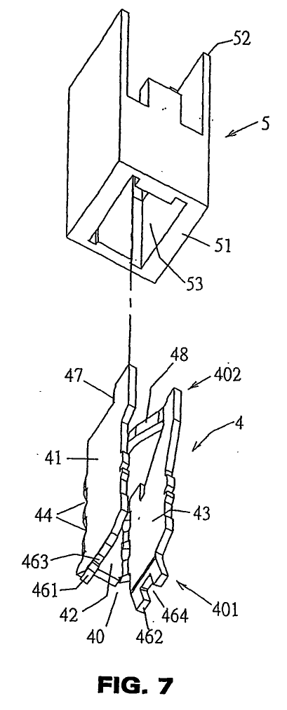

Referring now to FIGS. 4 to 6, a conductive terminal 4 of the present invention used in an electrical connector is similar with the prior art and connects between an electronic component (not shown) and a circuit board (not shown). The conductive terminal 4 pre-sets a solder ball 6 onto an end thereof.

The electrical connector comprises a plurality of conductive terminals 4 and an insulative housing 5.

The insulative housing 5 has a mounting surface 51 which is positioned proximate to the circuit board (such as motherboard of a computer) and a receiving surface 52 for supporting the electronic component (such as central processing unit, CPU). The insulative housing 5 defines a plurality of terminal channels 53 extending through the mounting surface 51 and the receiving surface 52. To easily illuminate, it is drawn in the FIGS. that the insulative housing 5 has a single terminal channel 53.

The conductive terminal 4 has a first wall 41, a second wall 42 connecting with one side of the first wall 41 in an approximately 90 degrees angle and a third wall 43 connecting with the other side of the second wall 42 in an approximately 90 degrees angle and opposite to the first wall 41 in some distance. The connecting corner of the first wall 41 and the second wall 42 defines a plurality of hollows 44 so as to make the connecting corner of the first wall 41 and the second wall 42 have lower intensity and the first wall 41 easily bend along the hollows 44. Similarly, the connecting corner of the third wall 43 and the second wall 42 defines a plurality of hollows 44 so as to make the third wall 43 easily bend along the hollows 44 to the second wall 42. The conductive terminal 4 respectively forms a mounting portion 401 and a contact portion 402 at opposite end thereof.

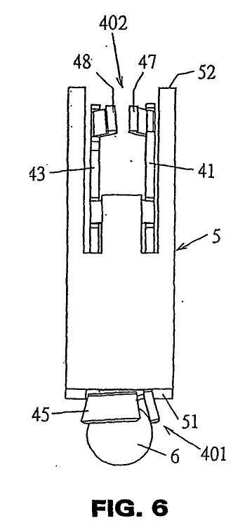

The mounting portion 401 has a pyramidal, or frustoconical, space 40 defined by a side wall 45 connecting the first wall 41. In manufacture, the side wall 45 is an elongated plate connected with the first wall 41 and formed by stamping with the first wall 41 at the same time. The elongated plate encircles a plane along a fictitious central line 451 as an axis which is similar with the extending long direction of the conductive terminal 4. And when encircling the side wall 45, it side face has a same out-fastigiated degrees with the fictitious central line 451 so as to expand far away from the contact portion 402 to define the pyramidal space 40 receiving the solder ball 6. As shown in FIG. 5, the pyramidal space 40 preferably does not have an enclosed top, but rather, the top portion of the pyramidal space 40 is open.

The contact portion 402 comprises a first spring arm 47 formed on one side of the first wall 41 adjacent to the receiving surface 52 and a second spring arm 48 formed on one side of the second wall 42 adjacent to the receiving surface 52. A free end of the first spring arm 47 and a free end of the second spring arm 48 are adjacent to form a spring receiving structure to provide an insert arm of an electrical component (not shown) inserting. Because the contact portion 402 is not the point of novelty of the present invention and its principle of electrically connecting is similar with a corresponding structure of the conductive terminal of the ZIF electrical connector (not shown), here it is not illuminated in detail.

Referring to FIG. 4 to FIG. 6, in assembly, the conductive terminal 4 inserts the corresponding terminal channels 53 of the insulative housing 5 from the mounting surface 51 of the insulative housing 5 so that the contact portion 402 is received in the terminal channels 53 and adjacent to the receiving surface 52 thereof, and the mounting portion 401 extends from the mounting surface 51 thereof. The pyramidal space 40 defined by the side wall 45 expands from one end near the terminal channels 53 to the direction faraway from the mounting surface 51 of the insulative housing 5, with the pyramidal opening 40 being greater farther away from the mounting surface 51. When the solder ball 6 contacts with the mounting portion 401, the pyramidal space 40 can receive the solder ball 6 through its cone-shaped structure. The inside surfaces of the side wall 45 slant toward inside in every direction so as to locate the solder ball 6 in the pyramidal space 40. And when the solder ball 6 melts, tin adheres to the inside surfaces of the side wall 45 so that the whole of the solder ball 6 and the pyramidal space 40 have easy orientation and steadily connecting effect.

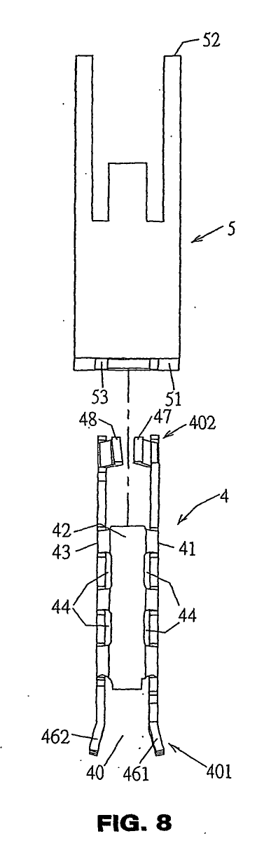

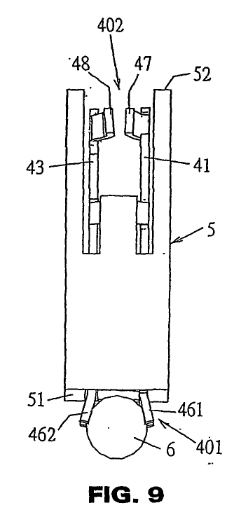

Referring to FIGS. 7 to 9, a conductive terminal 4 of another embodiment is different from the conductive terminal 4 of the first embodiment as above. The mounting portion 401 of the conductive terminal 4 comprises a first side arm 461 connecting with the first wall 41 and adjacent to one end of the mounting surface 51, and a second side arm 462 connecting with the third wall 43 and adjacent to one end of the mounting surface 51. The first side arm 461 and the second side arm 462 aslant extend out of the mounting surface 51 and apart each other to define a cone-shaped pyramidal space 40. Therefore, the pyramidal space 40 receives the solder ball 6 and the first side arm 461 and the second side arm 462 aslant locate the solder ball 6. In addition, an end of the first side arm 461 further defines a first recess 463 and an end of the second side arm 462 further defines a second recess 464. When the solder ball 6 melts, tin inflow into the first recess 463 and the second recess 464 so that the concretionary solder ball 6 not only adheres to the surface of the first side arm 461 and the second side arm 462 but also insets the first recess 463 and the second recess 464 to enhance fastness of the solder ball 6 and the mounting portion 401 connecting.

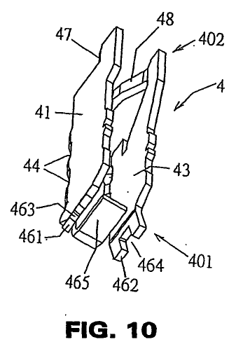

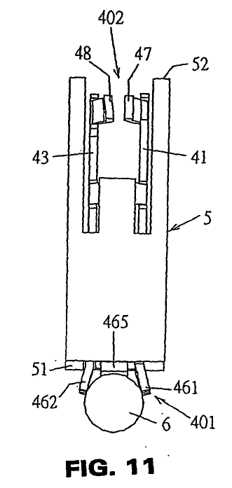

Referring to FIG. 10 and FIG. 11, the mounting portion 401 of the conductive terminal 4 also comprises a horizontal portion 465 connecting with the second wall 42. The horizontal portion 465 adjacent to one end of the mounting surface 51 and approximately 90-degrees bends from the second wall 42. The horizontal portion 465 is formed at the middle away from the first side arm 461 and the second side arm 462. The horizontal portion 465 can stop and strengthen to contact with the solder ball 6 so as to improve fastness of the solder ball 6 and the mounting portion 401 locating and connecting.

In conclusion, the conductive terminal 4 of the present invention is formed via the first wall 41, the second wall 42 and the third wall 43 stamping and bending. The mounting portion 401 of the conductive terminal 4 defines the pyramidal space 40 to locate the solder ball 6 so as to make the solder ball 6 adhere therein.

Although the present invention has been illustrated and described with respect to exemplary embodiment thereof, it should be understood by those skilled in the art that the various changes, omissions and additions may be made therein and thereto without departing from the spirit and scope of the present invention as set forth in the appended claims.

What is claimed is:

1. A stamped and formed conductive terminal capable of being received within a terminal channel defined in an insulative housing and between an electronic component and a circuit board, having a contact portion electrically connecting with the electronic component and a mounting portion electrically connecting with the circuit board via a solder ball, comprising:
a first wall, a second wall connecting with the first wall in a certain angle and a third wall connecting with the second wall in a certain angle and opposite to the first wall, and the mounting portion defining a pyramidal space extending out of the insulative housing for receiving the solder ball.

2. The conductive terminal of claim 1 in which the mounting portion defines the pyramidal space by using a side wall connecting with an end of the first wall which circles around a fictitious central line as an axis.

3. The conductive terminal of claim 1 in which the mounting portion comprises a first side arm connecting with an end of the first wall and a second side arm connecting with an end of the third wall, the first side arm and the second side arm separately extend out of the insulative housing and define the pyramidal space.

4. The conductive terminal of claim 3 in which the mounting portion of the conductive terminal comprises a horizontal portion connecting with the second wall, the horizontal portion is between the first side arm and the second side arm, and has a certain degrees therebetween.

5. The conductive terminal of claim 1 in which the contact portion comprises a first spring arm formed on the first wall and a second spring arm corresponding to the first-spring arm and formed on the second wall, the first spring arm and the second spring arm are adjacent to form a spring receiving structure.

6. The conductive terminal of claim 1 in which the pyramidal space is open at a top portion.

7. The conductive terminal of claim 1 in which a horizontal portion extends from one of the walls, the horizontal portion being located between the first and third walls.

8. The conductive terminal of claim 3 in which at least one of the side arms includes a recess.

9. An electrical connector for connecting between an electronic component and a circuit board via a plurality of solder balls soldering onto the circuit bard, having an insulative housing forming a mounting surface adjacent to the circuit board and a receiving surface for supporting the electronic component, the insulative housing defining a plurality of terminal channels extending through the mounting surface and the receiving surface, a plurality of stamped and formed conductive terminals respectively received in the corresponding terminal channels, comprising:
the conductive terminal having a first wall, a second wall connecting with the first wall in a certain angle and a third wall connecting with the second wall in a certain angle and opposite to the first wall, the conductive terminal forming a contact portion electrically connecting with the electronic component and a mounting portion electrically connecting with the circuit board via the solder ball, the mounting portion defining a pyramidal space extending out of the mounting surface of the insulative housing for receiving the solder ball.

10. The electrical connector of claim 9 in which the mounting portion of the conductive terminal defines the pyramidal space by using a side wall connecting with an end of the first wall which circles around a fictitious central line as an axis.

11. The electrical connector of claim 9 in which the mounting portion of the conductive terminal comprises a first side arm connecting with the first wall and adjacent to one end of the mounting surface and a second side arm connecting with the third wall and adjacent to one end of the mounting surface, and the first side arm and the second side arm aslant extend out of the mounting surface and are apart from each other to define a cone-shaped pyramidal space.
